(19) United States
(12) Patent Application Publication
(10) Pub. No.: US 2017/0012110 A1
(43) Pub. Date: Jan. 12, 2017

(54) Method for Filling a Trench and Semiconductor Device

(71) Applicant: Infineon Technologies Dresden GmbH, Dresden (DE)

(72) Inventors: Rolf Weis, Dresden (DE); Martin Bartels, Dresden (DE); Marko Lemke, Dresden (DE); Stefan Tegen, Dresden (DE)

(21) Appl. No.: 15/205,323

(22) Filed: Jul. 8, 2016

(30) Foreign Application Priority Data
Jul. 10, 2015 (DE) 102015111210.8

(51) Int. Cl. H01L 29/66; H01L 21/28; H01L 29/10; H01L 29/739; H01L 29/423

(52) U.S. Cl. CPC H01L 29/66348; H01L 29/7397; H01L 29/42304; H01L 29/1095; H01L 21/28008

(57) ABSTRACT

A method includes forming a first trench in a semiconductor body between two semiconductor fins, filling the first trench with a first filling material, partially removing the first filling material by forming a second trench such that the second trench has a lower aspect ratio than the first trench, and at least partially filling the second trench with a second filling material so as to form a continuous material layer on the first filling material. A semiconductor device includes a first trench in a semiconductor body between two semiconductor fins, the first trench being filled with a first filling material, and a second trench having a lower aspect ratio than the first trench and being at least partially filled with a second filling material which forms a continuous material layer on the first filling material.

### TECHNICAL FIELD

Embodiments of the present invention relate to a method for filling a trench, in particular a trench having a high aspect ratio in a power transistor.

### BACKGROUND

Power transistors, in particular power field-effect transistors (FETs), such as power MOSFETs (Metal Oxide Field-Effect Transistors) or power IGBTs (Insulated Gate Bipolar Transistors) are widely used as electronic switches in drive applications, such as motor drive applications, or power conversion applications, such as AC/DC converters, DC/AC converters, or DC/DC converters.

Power transistors are capable of blocking high voltages and that have a low specific on-resistance (the on-resistance multiplied with the semiconductor area (chip size) of the power transistor). In specific types of power transistors, but also in other applications, there is a need to fill trenches having a high aspect ratio with a filling material, such as a dielectric. Filling those trenches may include the formation of seams and voids which may have undesirable electrical effects.

There is, therefore, a need to provide a method for filling a trench in a semiconductor body with a filling material, thereby avoiding negative effects associated with defects in the filling material, such as seams or voids.

### SUMMARY

One embodiment relates to a method. The method includes forming a first trench in a semiconductor body between two semiconductor fins, filling the first trench with a first filling material, partially removing the first filling material by forming a second trench such that the second trench has a lower aspect ratio than the first trench, and at least partially filling the second trench with a second filling material thereby forming a continuous material layer on the first filling material.

Another embodiment relates to a semiconductor device. The semiconductor device includes a first trench in a semiconductor body between two semiconductor fins, wherein the first trench is filled with a first filling material. The semiconductor device further includes a second trench having a lower aspect ratio than the first trench and at least partially filled with a second filling material forming a continuous material layer on the first filling material.

Those skilled in the art will recognize additional features and advantages upon reading the following detailed description, and upon viewing the accompanying drawings.

### BRIEF DESCRIPTION OF THE DRAWINGS

Examples are explained with reference to the drawings. The drawings serve to illustrate the basic principle, so that only aspects necessary for understanding the basic principle are illustrated. The drawings are not to scale. In the drawings the same reference characters denote like features.

FIG. 1 illustrates a vertical cross sectional view of a power transistor, according to one embodiment;

FIG. 2 illustrates a top view of the power transistor shown in FIG. 1;

FIGS. 3A-3F illustrate one embodiment of a method for filling trenches in a semiconductor arrangement;

FIG. 4 illustrates a vertical cross sectional view of a semiconductor body including voids in filled trenches;

FIGS. 5A-5D illustrate one embodiment of a method for producing seam stop regions in filled trenches; and

FIGS. 6A-6C illustrate one embodiment of a method for producing contact electrodes above a structure shown in FIG. 5D.

### DETAILED DESCRIPTION

In the following detailed description, reference is made to the accompanying drawings. The drawings form a part of the description and by way of illustration show specific embodiments in which the invention may be practised. It is to be understood that the features of the various embodiments described herein may be combined with each other, unless specifically noted otherwise.

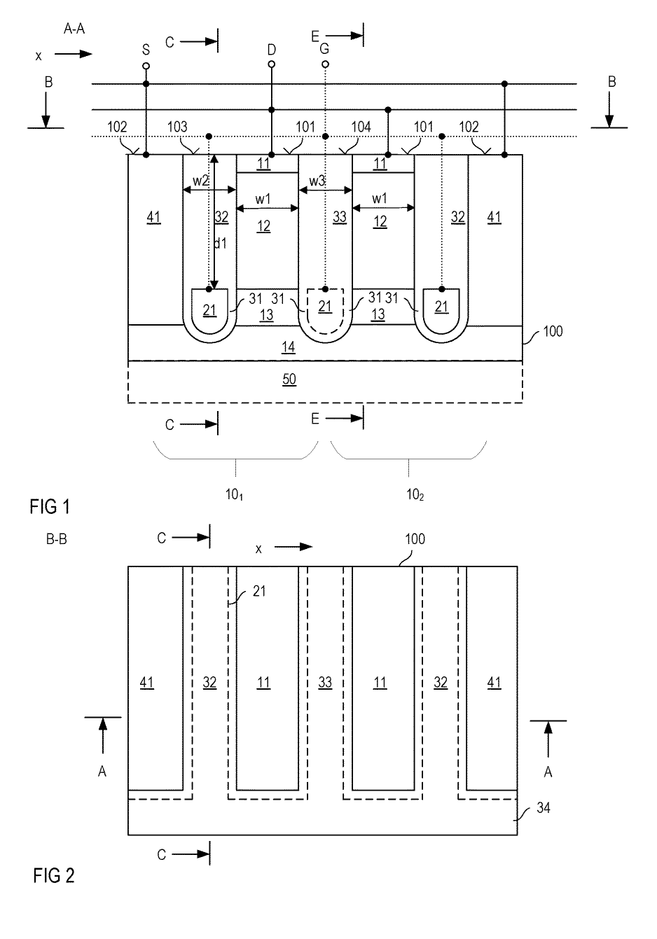

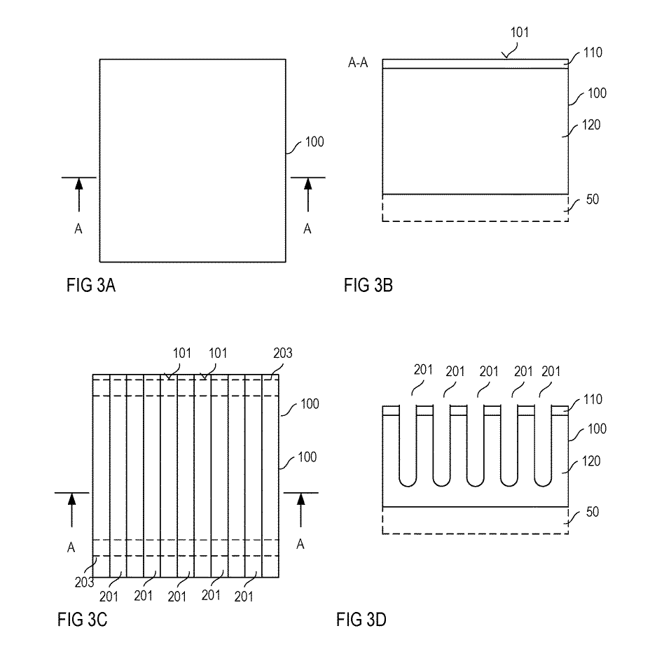

FIGS. 1 and 2 illustrate one embodiment of a power transistor. FIG. 1 shows a vertical cross sectional view of a portion of a semiconductor body 100 in which active device regions of the power transistor are integrated, and FIG. 2 shows a top view of the semiconductor body 100. Referring to FIGS. 1 and 2, the power transistor includes at least one transistor. In particular, the power transistor includes a plurality of substantially identical transistor cells. “Substantially identical” means that the individual transistor cells have identical device features, but may be different in terms of their orientation in the semiconductor body 100. In particular, the power transistor includes at least two transistor cells 101, 102 which, in the following, will be referred to as first and second transistor cells, respectively. In the following, when reference is made to an arbitrary one of the transistor cells or to the plurality of transistor cells, and when no differentiation between individual transistor cells is necessary, reference character 10 will be used to denote one or more of the plurality of transistor cells.

Referring to FIG. 1, each transistor cell 10 includes a drain region 11, a drift region 12, and body region 13 in a semiconductor fin of the semiconductor body 100. Further, a source region 14 adjoins the body region 13 of each transistor cell 10. The individual transistor cells 10 have the source region 14 in common. That is, the source region 14 is a continuous semiconductor region which adjoins the body regions 13 of the individual transistor cells 10, wherein the body regions 13 (as well as the drain regions 11 and the drift regions 12) of the individual transistor cells 10 are separate semiconductor regions. In different transistors, the source and/or the body region of each individual transistor may be structurally separated but electrically connected.

Referring to FIG. 1, each transistor cell 10 further includes a gate electrode 21 adjacent the body region 13 and dielectrically insulated from the body region 13 by a gate dielectric 31. Further, a field electrode 41 is dielectrically insulated from the drift region 12 by a field electrode dielectric 32 and is electrically connected to the source region 14.

Referring to FIG. 1, the gate electrode 21, the gate dielectric 31, and the field electrode dielectric 32 of each transistor cell 10 are arranged in a first trench adjacent the drain region 11, the drift region 12, and the body region 13 of the corresponding transistor cell 10. The field electrode may terminate the power transistor in lateral direction.

The semiconductor fin that includes the drain region 11, the drift region 12 and the body region 13 of the first transistor cell 101 is separated from the semiconductor fin which insulates the drain region 11, the drift region 12, and the body region 13 of the second transistor cell 102 by a second trench which includes an electrically insulating, or dielectrically insulating material 33.

The first transistor cell 101 and the second transistor cell 102 may be substantially axially symmetric, with the symmetry axis going through the second trench with the insulating material 33. However, this is only an example. Other arrangements than symmetrical arrangements are possible as well.

Referring to FIG. 1, the individual transistor cells 10 are connected in parallel by having their drain regions 11 electrically connected to a drain node D, by having their gate electrodes 21 electrically connected through a gate node G, and by having the source region 14 connected to a source node S. An electrical connection between the drain regions 11 and the drain node D is only schematically illustrated in FIG. 1. This electrical connection can be implemented using conventional wiring arrangements implemented on top of a semiconductor body. Equivalently, an electrical connection between the field electrodes 41 and the source node S are only schematically illustrated in FIG. 1. Electrical connections between the gate electrode 21 and the gate node G are illustrated in dotted lines in FIG. 1. These gate electrodes 21 are buried below the field electrode dielectric 32 in the first trenches.

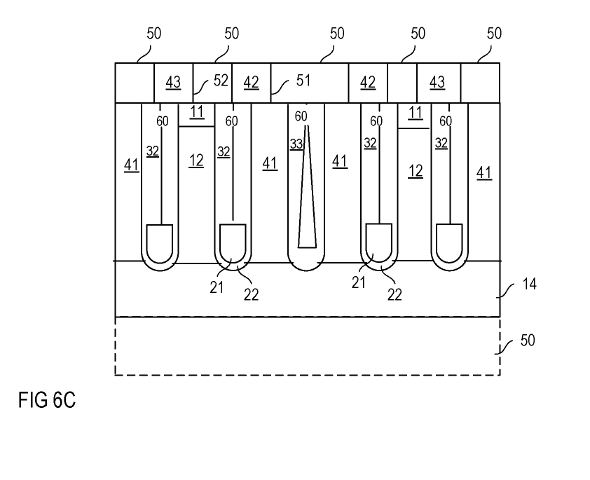

Referring to FIG. 1, reference character 101 denotes surfaces of the semiconductor fins of the individual transistor cells 10. Reference character 102 denotes surfaces of the field electrodes 41, reference character 103 denotes surfaces of the field electrode dielectrics 32, and reference character 104 denotes surfaces of the insulating material 33 in the second trenches. These surfaces 101, 102, 103, and 104 may be substantially in the same horizontal plane. The drain regions 11 may be contacted at the surfaces 101 in order to connect the drain regions 11 to the drain node D, and the field electrodes 41 may be contacted in the surfaces 102 in order to connect the field electrodes 41 to the common source node S. One way of how the drain regions 11 and the field electrodes 41 (and therefore the source region 14) may be contacted is explained with reference to FIGS. 6A-6C herein below.

Referring to FIG. 1, the semiconductor fin of each transistor cell 10 has a first width w1. This first width w1 corresponds to the distance between the first trench adjoining the semiconductor fin and accommodating the field electrode dielectric 32 and the second trench adjoining the semiconductor fin and accommodating the insulating material 33. The first width w1 may be selected from a range of between 10 nm (nanometers) and 100 nm, for example. The semiconductor fins of the individual transistor cells 10 may have substantially the same first width w1 or may have a mutually different first width w1.

A width w2 of the field electrode dielectric 32 is, for example, between 30 nm and 300 nm. As, referring to FIG. 1, the field electrode dielectric 32 fills the trench above the gate electrode 21 and the gate dielectric 31, the width w2 of the field electrode dielectric 32 is greater than a thickness of the gate dielectric 31. The same applies to a width w3 of the insulating material 33.

The first width w1 is the dimension of the semiconductor fin in a first horizontal direction x of the semiconductor body 100. Referring to FIG. 2, which shows a top view of the semiconductor body 100, the semiconductor fin with the drain region 11, the drift region 12 and the body region 13 (whereas FIG. 2 only shows the drain region 11) has a length in a direction perpendicular to the first horizontal direction x. In FIG. 2, the dotted lines show the position of the gate electrodes in the first trenches below the field electrode dielectric 32. The length of the semiconductor fin is much longer than the first width w1. A ratio between the length and the width w1 may be at least 2:1, at least 100:1, at least 1000:1, or at least 10000:1, for example. The same applies to a ratio between a length of the field electrode dielectric 32 and the corresponding width w2, respectively.

Further referring to FIG. 1, a depth d1 of the field electrode dielectric 32 and the insulating material 33 is much greater than the width w2 and the width w3, respectively. A ratio between the depth d1 and the width w2 or the width w3 may be at least 10:1, at least 20:1, or at least 100:1, for example.

The power transistor shown in FIGS. 1-2 is a FET (Field-Effect Transistor) and, more specifically, a MOSFET (Metal Oxide Field-Effect Transistor) or an IGBT (Insulated Gate Bipolar Transistor). It should be noted that the term MOSFET as used herein denotes any type of field-effect transistor with an insulated gate electrode (often referred to as IGFET) independent of whether the gate electrode includes a metal or another type of electrically conducting material, and independent of whether the gate dielectric includes an oxide or another type of dielectrically insulating material. The drain regions 11, drift region 12, body regions 13, and the source region 14 of the individual transistor cells 10 may include a conventional monocrystalline semiconductor material such as, for example, silicon (Si), germanium (Ge), silicon carbide (SiC), gallium nitride (GaN), gallium arsenide (GaAs), or the like. The gate electrodes 21 may include a metal, TiN, carbon or a highly doped polycrystalline semiconductor material, such as polysilicon or amorphous silicon. The gate dielectrics 31 may include an oxide such as, for example, silicon dioxide (SiO₂), a nitride such as, for example, silicon nitride (Si3N4), an oxinitride or the like. Like the gate electrodes 21, the field electrodes 41 may include a metal, TiN, carbon or a highly doped polycrystalline semiconductor material. Like the gate dielectrics 31, the field electrode dielectrics 32 may include an oxide or a nitride or an oxinitride. The same applies to the insulating material 33.

The power transistor can be implemented as an n-type transistor, or as a p-type transistor. In the first case, the source region 14 and the drift region 12 of each transistor cell 10 is n-doped. In the second case, the source regions 14 and the drift region 12 of each transistor cell 10 is p-doped. Further, the transistor can be implemented as an enhancement (normally-off) transistor, or as a depletion (normally-on) transistor. In the first case, the body regions 13, have a doping type complementary to the doping type of the source region 14, and the drift region 12. In the second case, the body region 13 has a doping type corresponding to the doping type of the source region 14 and the drift region 12. Further, the transistor can be implemented as a MOSFET or as an IGBT. In a MOSFET, the drain region 11 has the same doping type as the source region. An IGBT (Insulated Gate Bipolar Transistor) is different from a MOSFET in that the drain region 11 (which is also referred to as collector region in an IGBT) has a doping type complementary to the doping type of the source and drift regions 14, 12.

Referring to FIG. 1, the source region 14 is a buried semiconductor region (semiconductor layer), which is distant to the surfaces 101 of the individual semiconductor fins. As illustrated in dashed lines in FIG. 1, the source region 14 may adjoin a carrier 50, which may provide for a mechanical stability of the power transistor. The carrier 50 may be a semiconductor substrate. This semiconductor substrate may have a doping type complementary to the doping type of the source region 14. The carrier 50 may also include a semiconductor substrate and an insulation layer on the substrate, for example, with the source region 14 adjoining the insulation layer of the carrier 50.

In the power transistor shown in FIG. 1, the field electrode 41 is used to electrically connect the buried source region 14 to the source node S. The gate electrode 21 of each transistor cell 10 is arranged in the first trench, adjacent the body region 13, and dielectrically insulated from the body region 13 by the gate dielectric 31. Referring to FIG. 1, the gate electrode 21 of one transistor cell may not only be arranged in the first trench but also in the second trench below the insulating material 33, adjacent the body regions 13, and dielectrically insulated from the body region 13, by the gate dielectric 31. Like the gate electrode 21 in the first trench, the gate electrode 21 in the second trench may be connected to the gate node G.

In the transistor shown in FIG. 1, depth d1 of the trenches may be much greater than their width w2, w3, so that these trenches have a high aspect ratio, which is the ratio between the depth d1 and the width w2 and w3, respectively. Referring to the above, the aspect ratio is higher than 10:1, or even higher than 100:1. When filling a trench having a high aspect ratio with a filling material, such as a dielectric, defects such as voids or seams, may occur. For example, such defects may result in an electrically conducting path from the surface 101 to the gate electrode 21, or may act like field electrodes. This is highly undesirable.

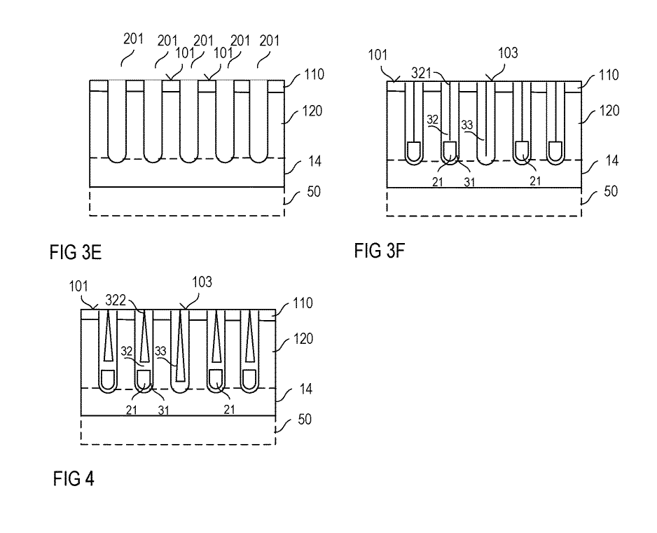

FIGS. 3A-3F show one embodiment of a method for filling a trench having a high aspect ratio, whereas this method avoids the problems outlined above. In the following, the method is explained in context with forming a transistor device as shown in FIGS. 1 and 2. However, the method is not restricted to be used in this specific context but may be used anywhere where it is desired to fill a trench having a high aspect ratio.

FIGS. 3A-3F show the semiconductor body during/after process steps of the method. FIG. 3A shows a top view and FIG. 3B shows a vertical cross sectional view of the semiconductor body 100 at the beginning of the method. Referring to FIG. 3B, the semiconductor body 100 may include two semiconductor layers, a first semiconductor layer 110 forming drain regions of the transistor cells in the finished power transistor, and a second semiconductor layer 120 in which drift regions 12, body regions 13 and the source region 14 of the individual transistor cells are formed. Optionally, the second semiconductor layer 120 adjoins the carrier 50. The carrier 50 may include an electrically insulating material, such as a ceramic. The carrier 50 may also be a semiconductor substrate, for example. The semiconductor substrate may have the same doping type as the second semiconductor layer 120, or a doping type complementary to the doping type of the second semiconductor layer 120. When the carrier is a semiconductor substrate the first and second layers 110, 120 may be part of an epitaxial layer grown on the substrate 50. The doping concentration of the second layer 120 may correspond to a basic doping concentration of the epitaxial layer formed during the growth process. The first layer 110 is, for example, a doped layer formed by at least one of an implantation and diffusion process. In another example, the first and second layers 110, 120 may be formed in the semiconductor substrate by at least one of an implantation and diffusion process.

FIG. 3C shows a top view of the semiconductor body 100, and FIG. 3D shows a vertical cross sectional view of the semiconductor body 100 after process steps in which at least one trench 201 is formed in the first surface 101 of the semiconductor body 100. In the embodiment shown in FIGS. 3C and 3D, a plurality of trenches is formed. These trenches 201 extend through the first layer 110 into the second layer 120 and may be formed using a conventional etching process, such as, for example, an anisotropic etching process. According to one embodiment (not shown in FIG. 3C) the method includes etching at least one further trench perpendicular to the trenches shown in FIG. 3C so as to obtain a structure as shown in FIG. 2.

Referring to FIG. 3E, the method further includes forming the source region 14 in the second semiconductor layer 120. Forming the source region 14 may include implanting dopant atoms into the bottoms of the trenches 201 and diffusing the implanted dopant atoms in the second semiconductor layer 120. A protection layer (not shown) may cover top surfaces 101 of the semiconductor fins formed by etching the trenches in order to prevent dopant atoms from being implanted into the semiconductor fins.

In one example, the protection layer is omitted so that dopant atoms are implanted into the bottom of the trenches 201 and into the semiconductor fins close to the surface 101. Those dopant atoms implanted into the fins (after a diffusion process) form the drain region. In this example, the source region 14 and the drain regions 11 are formed by the same process steps. In this case forming the first layer 110 is omitted.

According to another example (not shown), the source region 14 is formed before forming the trenches 201 (that is, in the semiconductor body 100 shown in FIG. 10B) by implanting dopant atoms via the first surface 101 into the semiconductor body 100. According to yet another example, the source region 14 is formed in an epitaxy process as part of the second layer 120.

Referring to FIG. 3F, further method steps include forming the gate electrodes 21 and the gate dielectrics 31 at least in those trenches forming the first trenches in the finished power transistor. In the example shown in FIG. 3F, gate electrodes 21 and gate dielectrics 31 are formed in some of the trenches 201, that is, in those trenches forming the first trenches in the finished power transistor. Forming the gate electrodes 21 and the gate dielectrics 31 may include forming the gate dielectric 31 on the bottoms and at least on lower sidewall sections of the individual trenches 201. “Lower sidewall sections” of the individual trenches 201 are those sections of the individual trenches that are adjacent the body regions 13 in the finished power transistor. Forming the gate dielectrics 31 may include an oxidation process. Forming the gate electrodes 21 may include filling the trenches 201 with an electrode material in those regions adjacent the body regions 13 in the finished power transistor. This may include completely filling the trenches 201 with the electrode material, and recessing the electrode material down to adjacent the body region 13. Above the gate electrodes 21, the trenches 201 are filled with a dielectrically insulating material. This dielectrically insulating material, optionally together with parts of the gate dielectric 31, forms the field electrode dielectrics 32 in the first trenches of the finished power transistor and the insulating material 33 in the second trenches of the finished power transistor.

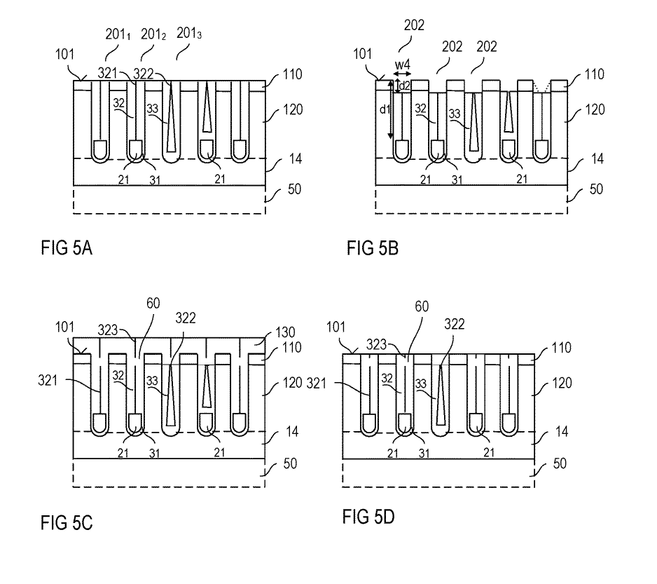

For example, filling the trenches 201 above the gate electrodes 21 includes a conformal deposition process such as a chemical vapor deposition (CVD) process, a low pressure chemical vapor deposition (LPCVD) process, or a high temperature oxide (HTO) process. During such process, a filling material layer is deposited on the gate electrode 21 and sidewalls of the trenches 201. This material layer grows on the gate electrode 21 as well as on both sides of each trench 201 until the trench 201 is completely filled. When a trench with a high aspect ratio is completely filled in a deposition process three different scenarios may occur. (1) The deposited material fills the trench without leaving a seam or a void. (2) As shown in FIG. 3F, a seam 321 arises from the point where the sidewall layers merge during deposition. (3) Referring to FIG. 4, a void 322 is generated if the trench opening is closed in the deposition process before lower trench sections have been filled completely. Seams 321 and voids 322 are undesirable, as they may provide a conducting path or a weakened isolation between an upper trench section, which is a section close to the surface 101, and the gate electrode 21 in the lower trench section. Right after filling the trench, a seam or void may be spaced apart from a gate electrode 21 in the lower trench section. However, during subsequent processing of the semiconductor body, such as further etching processes, the seam or void may extend deeper. Furthermore, this extended seam or void may be filled unintentionally with an electrically conducting material, such as doped polysilicon, titanium titanium-nitride, tungsten, or the like, thereby forming an electrically conducting path in the filled trench. This conducting material may be used in process sequences that form interconnects (wiring arrangements) above the surface 101 of the semiconductor body 100. However, those sequences are not explained in further detail herein.

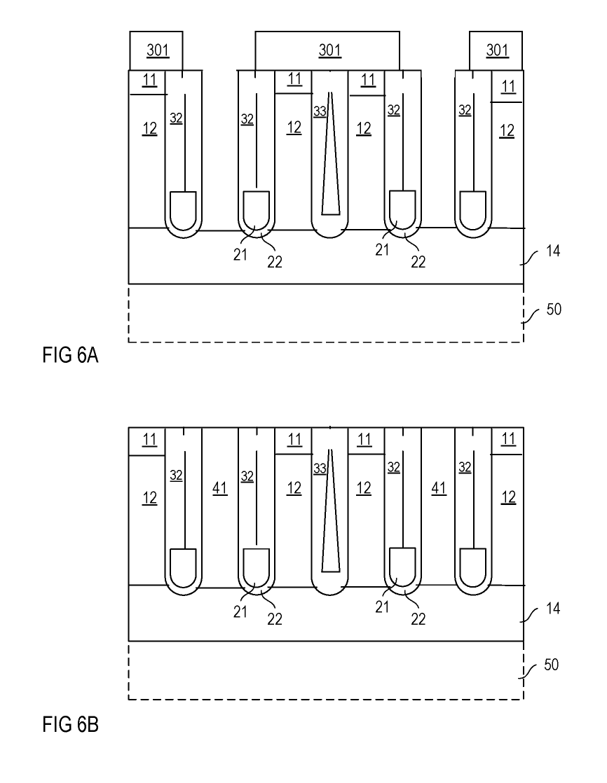

FIGS. 5A-5D illustrate one embodiment of a method that helps to prevent those electrical connections (short circuits) between the upper trench section and the gate electrode 21. FIGS. 5A-5D show vertical cross sectional views of the semiconductor body 100 during/after individual process steps. The method shown in FIGS. 5A-5D is based on a structure obtained by the process sequence explained with reference to FIGS. 3A-3F and 4, that is, a structure that may include seams ad/or voids. For the purpose of explanation, FIG. 5A shows a structure that includes seams 321 and voids 322.

Referring to FIG. 5B, the method includes removing the filling material 32, 33 (field electrode dielectric and insulation layer) from upper trench sections. This may include an etching process that etches the filling material 32, 33 selectively relative to the material of the semiconductor body 100. This process results in second trenches 202 having a width w4 and a depth d2. The second trench 202 may be aligned with the first trench 201 so that the width w4 may substantially correspond to the width w2, w3 of the respective first trench. The depth d2 is less than the depth d1 of the first trenches 201 so that the second trenches 202 do not extend down to the gate electrodes 21. According to one embodiment, an aspect ratio between the second depth d2 and the width w4 of the second trenches 202 is at most 1:1, at most 2:1, at most 4:1, or at most 6:1.

According to one embodiment, etching the second trenches 202 includes completely removing the filling material 32, 33 along sidewalls of the second trenches. According to another embodiment, forming the second trenches 202 includes forming the second trenches 202 with tapered sidewalls such that part of the filling material 23, 33 remains along the sidewalls of the second trenches 202. A second trench 202 with tapered sidewalls is shown in dotted lines in the right section of FIG. 5B.

Referring to FIG. 5C, the second trenches are at least partly filled. This may include depositing another material layer 130 on the first surface 101 of the semiconductor body 100 and in the second trenches 202. The type of material of this material layer 130 may correspond to the material forming the field electrode dielectric 32 and the insulation layer 33 remaining in the lower trench sections. By virtue of the low aspect ratio of the second trenches 202 (relative to the aspect ratio of the first trenches 201) the second trenches 202 are either filled without the formation of seams (seamless) or voids, or filled such that a material layer 60 is formed on the bottom of the second trenches. This material layer 60 covers seams 321 or voids 322 that may have formed in the process explained with reference to FIGS. 3A-3F and 4. Thus, even if a further seam 323 or void (not shown) forms in the material layer 130 in the second trenches 202 the material layer 60, which may be referred to as seam stop layer (or void stop layer), prevents that the seam 321 (or the void 322) in the lower trench section is connected with the seam 322 (the void) in the upper trench section. This seam stop layer 60 prevents short circuits or other undesired effects explained above.

According to one embodiment, at least partly filling the second trench 202 includes a non-conformal deposition process such as, for example, a high density plasma (HDP) process. A non-conformal process mainly forms a material layer on the bottom of a trench. In a method of the type shown in FIGS. 5A-5D, employing a non-conformal deposition process ion filling the second trench 202 provides for covering the seam or void at the bottom of the second trench 202. Filling the second trench 202 may include completely filling the second trench with the same material such as, for example, an electrically insulating material. According to another embodiment the bottom and sidewalls of the second trench 202 are lined with an electrically insulating material and a residual trench remaining after lining the bottom and the sidewalls is filled with another material such as, for example, polysilicon.

Referring to the above, filling the second trenches 202 may include a deposition process in which a material layer 130 is deposited in the second trenches 202 and on the surface 101 of the semiconductor body 100. In this case the material layer may be removed from above the surface 101. This may include one of an etching process and a polishing process. According to one embodiment, the polishing process is a CMP (Chemical Mechanical Polishing) process. FIG. 5D shows the structure after such removal of the material layer 130 from above the surface 101. In this structure, there are no continuous seams or voids that run all the way from the top to the bottom of the trenches, whereas those trenches may be trenches including a gate electrode 21 or trenches without such gate electrode. If any seams 321, 323 or voids 322 have been formed the seam stop region 60 isolates a first seam 321 or void 322 in the lower trench section from a second seam or void in the upper trench section. The position of the seam stop region relative to the surface 101 is dependent on how deep the second trenches 202 are.

FIGS. 6A-6C show further method steps for forming a transistor device as shown in FIG. 1 based on a semiconductor arrangement shown in FIG. 5D. Referring to FIG. 6A, the method includes, in each transistor cell of the finished device, etching a trench 203 between the trench including the gate electrode 21 and the field electrode dielectric 32 and the trench including the insulation layer 33 (whereas the same type of material may be used to for the field electrode dielectric 32 and the insulation layer 33). These trenches extend down to the source region 14. Forming these trenches may include an etching process that etches the semiconductor material of the semiconductor body 100 relative to the field electrode dielectric 32 and the insulation layer 33. An etch mask may cover those regions of the first semiconductor layer 110 and the second semiconductor layer 120 that are not to be removed. These remaining sections of the first semiconductor layer 110 and the second semiconductor layer 120 form the source region 11 and the drift region 12 in each transistor cell.

Referring to FIG. 6B, the trenches 203 are filled with an electrode material in order to form the combined source and field electrode 41. Examples of the electrode material include a metal, a silicide, a highly doped polysilicon, or the like. Filling the trenches 203 may include depositing the electrode material in the trenches and on the surface of the structure, and then planarizing the resulting structure so as to remove the electrode layer from above the source regions 11.

Referring to FIG. 6C, the method further includes, in each transistor cell, forming at least one of a source contact electrode 42 electrically connected to the combined source and field electrode 41 and a drain electrode 43 electrically connected to the drain region 11. Forming these electrodes 42, 43 may include forming an insulation layer 50 above the arrangement, forming, in the insulation layer 50, a first contact hole 51 above the source electrode 41 and a second contact hole 52 above the drain region 11, and forming the source contact electrode 42 in the first contact hole 51 and the drain electrode 43 in the second contact hole 52. The source contact electrode 42 and the drain electrode 43 may be formed to overlap the field electrode dielectric 32 and the insulation layer 33 (as shown in FIG. 6C). By virtue of the seam stop region 60 a short circuit between one of these electrodes 42, 43 and the gate electrode 21 can be prevented.

Embodiments of the current invention have been disclosed by means of a power transistor. However, the described method may not only be used to fill trenches in power transistors. It may be used to fill trenches in any other semiconductor device as well.

It is to be understood that the features of the various embodiments described herein may be combined with each other, unless specifically noted otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method, comprising:
forming a first trench in a semiconductor body between two semiconductor fins;
filling the first trench with a first filling material;
partially removing the first filling material by forming a second trench such that the second trench has a lower aspect ratio than the first trench; and
at least partially filling the second trench with a second filling material so as to form a continuous material layer on the first filling material.

2. The method of claim 1, wherein each of the first filling material and the second filling material is a dielectric.

3. The method of claim 1, wherein the first filling material and the second filling material are of the same material type.

4. The method of claim 1, wherein the second trench is aligned with the first trench.

5. The method of claim 4, wherein an aspect ratio of the first trench is at least 10:1.

6. The method of claim 4, wherein an aspect ratio of the second trench is at most 6:1.

7. The method of claim 1, wherein filling the first trench comprises a deposition process.

8. The method of claim 1, wherein filling the second trench comprises a deposition process.

9. The method of claim 1, further comprising:
forming a gate electrode in the first trench before filling the trench with the first filling material.

10. The method of claim 1, wherein filling the first trench comprises completely filling the first trench.

11. The method of claim 1, wherein filing the first trench comprises using a conformal deposition process.

12. The method of claim 1, wherein at last partially filling the second trench comprises completely filling the second trench.

13. The method of claim 1, wherein at last partially filling the second trench comprises partly filing the second trench such that at least a bottom of the second trench is covered with the second filling material.

14. The method of claim 1 wherein at last partially filling the second trench comprises using a non-conformal deposition process.

15. The method of claim 1, further comprising:
forming a gate dielectric and a gate electrode in the first trench before filling the first trench with the first filling material.

16. The method of claim 15, further comprising:
forming a body region adjoining the gate dielectric in the semiconductor body.

17. The method of claim 16, further comprising:
forming a drift region adjoining the body region and a drain region in one of the two semiconductor fins; and
at least partially replacing the other semiconductor fin with an electrically conducting material.

18. The method of claim 1, further comprising:
forming a gate electrode in the first trench before filling the first trench.

19. The method of claim 1, wherein forming the second trench comprises forming the second trench with tapered sidewalls.

20. A semiconductor device, comprising:
a first trench in a semiconductor body between two semiconductor fins, the first trench being filled with a first filling material; and
a second trench having a lower aspect ratio than the first trench and being at least partially filled with a second filling material which forms a continuous material layer on the first filling material.

21. The semiconductor device of claim 20, further comprising:
a gate electrode and a gate dielectric in the first trench below the first filling material.

22. The semiconductor device of claim 21, further comprising:
a body region arranged in one of the two semiconductor fins and adjoining the gate dielectric;
a drift region adjoining the body region; and
a drain region adjoining the drift region.
